(19) United States
(12) Patent Application Publication
(10) Pub. No.: US 2017/0219643 A1
(43) Pub. Date: Aug. 3, 2017

(54) JITTER DETECTION CIRCUIT AND SEMICONDUCTOR SYSTEM USING THE SAME

(71) Applicant: SK hynix Inc., Icheon-si Gyeonggi-do (KR)

(72) Inventor: Kwan Dong KIM, Cheongju-si Chungcheongbuk-do (KR)

(21) Appl. No.: 15/145,030

(22) Filed: May 3, 2016

(30) Foreign Application Priority Data
Feb. 1, 2016 (KR) 10-2016-0012099

(51) Int. Cl. G01R 29/26; H03L 7/06

(52) U.S. Cl. CPC G01R 29/26; H03L 7/06

(57) ABSTRACT

A semiconductor system may include a first semiconductor device configured to output a clock, receive and output data, and detect a jitter of a transmission path according to a level combination of a plurality of monitoring signals. The semiconductor system may also include a second semiconductor device configured to generate the plurality of monitoring signals of which the level combination is changed according to phase differences between an internal clock generated through the transmission path for transmitting the clock and a plurality of divided clocks obtained by dividing the frequency of the clock.

### CROSS-REFERENCES TO RELATED APPLICATIONS

The present application claims priority under 35 U.S.C. §119(a) to Korean application number 10-2016-0012099, filed on Feb. 1, 2016, which is incorporated by reference in its entirety.

### BACKGROUND OF THE INVENTION

1. Technical Field

The present invention relates to a jitter detection circuit capable of detecting a jitter in a transmission path and a semiconductor system using the same.

2. Related Art

With the increase in integration density of semiconductor devices, semiconductor devices have been continuously improved in order to enhance the operating speed thereof. Recently, a so-called synchronous device has emerged, which can be operated in synchronization with a clock applied from outside the semiconductor device, in order to enhance the operating speed of the semiconductor device.

The clock applied from outside is transmitted through an external transmission path coupled to an external device, and then supplied through an internal transmission path to a circuit which is operated in synchronization with the clock.

Various factors which occur in the transmission path through which the clock is transmitted may cause a jitter. The various factors may include crosstalk, impedance mismatch, PVT (Process Voltage Temperature) variation, and ISI (Inter Symbol Interference). Therefore, there is a demand for a technology capable of detecting jitter which occurs in a clock.

### SUMMARY OF THE INVENTION

Embodiments of the present disclosure are directed to a jitter detection circuit capable of detecting a jitter which occurred in an internal transmission path for transmitting a clock, and a semiconductor system using the same.

In one embodiment, a jitter detection circuit may include a multi-phase clock generation circuit configured to generate a plurality of divided clocks by dividing a frequency of a clock inputted from outside the multi-phase clock generation circuit and controlling a phase of the clock, and generate a locking signal which is enabled when a phase control operation for the plurality of divided clocks is completed; a transmission path configured to transmit the clock as an internal clock; and a monitoring circuit configured to generate a plurality of monitoring signals of which a level combination is changed according to phase differences between the internal clock and the plurality of divided clocks.

In another embodiment, a semiconductor system may include a first semiconductor device configured to output a clock, receive and output data, and detect a jitter of a transmission path according to a level combination of a plurality of monitoring signals; and a second semiconductor device configured to generate the plurality of monitoring signals of which the level combination is changed according to phase differences between an internal clock generated through the transmission path for transmitting the clock and a plurality of divided clocks obtained by dividing the frequency of the clock.

### BRIEF DESCRIPTION OF THE DRAWINGS

FIG. 1 is a block diagram illustrating a configuration of a semiconductor system in accordance with an embodiment.

FIG. 2 is a block diagram illustrating a configuration of a monitoring circuit included in the semiconductor system of FIG. 1.

FIG. 3 is a timing diagram for describing an operation of a frequency comparison circuit of FIG. 2.

FIG. 4 is a block diagram illustrating a configuration of a monitoring signal generation circuit included in the monitoring circuit of FIG. 2.

FIG. 5 is a block diagram illustrating a configuration of a monitoring signal generation circuit included in the monitoring circuit of FIG. 2.

FIG. 6 is a diagram illustrating a configuration of a comparison circuit included in the monitoring signal generation circuit of FIG. 5.

FIG. 7 is a block diagram illustrating a configuration of a counting signal generation circuit included in the monitoring signal generation circuit of FIG. 5.

FIG. 8 is a graph for describing an operation of a counting signal generation circuit in accordance with an embodiment.

FIG. 9 is a block diagram illustrating a configuration of a semiconductor system in accordance with another embodiment.

FIG. 10 is a block diagram illustrating a configuration of a monitoring circuit included in the semiconductor system of FIG. 9.

FIG. 11 is a diagram illustrating a configuration of an electronic system to which the semiconductor devices and the semiconductor system illustrated in FIGS. 1 to 10 are applied.

### DESCRIPTION OF SPECIFIC EMBODIMENTS

Embodiments of the disclosure will hereinafter be described in detail with reference to the accompanying drawings. It should be noted that the drawings are not to precise scale and may be exaggerated in thickness of lines or sizes of components for descriptive convenience and clarity only. Furthermore, the terms as used herein are defined by taking functions of the disclosure into account and can be changed according to the custom or intention of users or operators. Therefore, definition of the terms should be made according to the overall disclosures set forth herein.

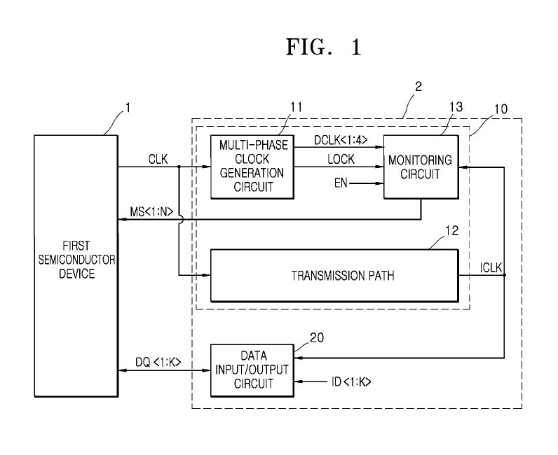

As illustrated in FIG. 1, a semiconductor system in accordance with an embodiment may include first and second semiconductor devices 1 and 2. The second semiconductor device 2 may include a jitter detection circuit 10 and a data input/output circuit 20.

The first semiconductor device 1 may output a clock CLK, receive and output first to Kth data DQ<1:K>, and receive first to Nth monitoring signals MS<1:N>. The clock CLK may be set to a signal which periodically toggles. The first to Kth data DQ<1:K> and the first to Nth monitoring signals MS<1:N> may be transmitted through lines which transmit one or more of an address, command, and data. The first to Kth data DQ<1:K> and the first to Nth monitoring signals MS<1:N> may be sequentially transmitted through one line, or may be transmitted through separate lines. The first to Nth monitoring signals MS<1:N> may include jitter information of a transmission path 12 installed in the second semiconductor device 2 which will be described below. That is, the first semiconductor device 1 may detect a jitter of the transmission path 12 installed in the second semiconductor device 2 through the first to Nth monitoring signals MS<1:N>.

The jitter detection circuit 10 may include a multi-phase clock generation circuit 11, the transmission path 12, and a monitoring circuit 13.

The multi-phase clock generation circuit 11 may generate first to fourth divided clocks DCLK<1:4> by dividing a frequency of the clock CLK inputted from outside the multi-phase clock generation circuit 11, and controlling phases of the first to fourth divided clocks DCLK<1:4>. The multi-phase clock generation circuit 11 may generate a locking signal LOCK which is enabled when a phase control operation for the first to fourth divided clocks DCLK<1:4> is completed. The multi-phase clock generation circuit 11 may be implemented with a general PLL circuit or a DLL circuit which controls a phase of the clock CLK.

The transmission path 12 may transmit the clock CLK as an internal clock ICLK. The transmission path 12 may be set to a path for transmitting a signal in a general semiconductor device. While the transmission path 12 transmits a signal, a jitter may irregularly occur according to PVT variations.

The monitoring circuit 13 may generate first to Nth monitoring signals MS<1:N> of which a level combination is changed according to phase differences between the internal clock ICLK and the first to fourth divided clocks DCLK<1:4>.

That is, the jitter detection circuit 10 may generate the first to Nth monitoring signals MS<1:N>, based on the phase differences between the first to fourth divided clocks DCLK<1:4> and the internal clock ICLK generated through the transmission path 12.

The data input/output circuit 20 may transmit the first to Kth data DQ<1:K> inputted from outside the data input/output circuit 20 as first to Kth internal data ID<1:K> in synchronization with the internal clock ICLK during a write operation. The data input/output circuit 20 may transmit the first to Kth internal data ID<1:K> as the first to Kth data DQ<1:K> in synchronization with the internal clock ICLK during a read operation. The first to Kth internal data ID<1:K> may indicate data stored in memory cells (not illustrated) included in the second semiconductor device 2.

That is, the second semiconductor device 2 may generate the first to Nth monitoring signals MS<1:N> of which the level combination is changed according to the phase differences between the internal clock ICLK, generated through the transmission path 12 for transmitting the clock CLK, and the first to fourth divided clocks DCLK<1:K>, obtained by dividing the frequency of the clock CLK. The second semiconductor device 2 may receive or output the first to Kth data DQ<1:K> in synchronization with the internal clock ICLK.

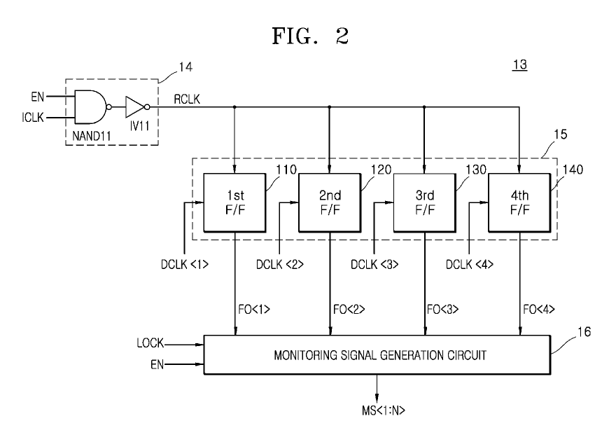

Referring to FIG. 2, the monitoring circuit 13 in accordance with a present embodiment may include a logic circuit 14, a frequency comparison circuit 15, and a monitoring signal generation circuit 16.

The logic circuit 14 may include a NAND gate NADN11 and an inverter IV11, and generate a reference clock RCLK by buffering the internal clock ICLK in response to an enable signal EN. When the enable signal EN is enabled to a logic high level, the logic circuit 14 may generate the reference clock RCLK by buffering the internal clock ICLK. The enable signal EN may be enabled to detect a jitter of the transmission path 12.

The frequency comparison circuit 15 may include a first flip-flop 110, a second flip-flop 120, a third flip-flop 130, and a fourth flip-flop 140.

The first flip-flop 110 may latch the reference clock RCLK at a time that the first divided clock DCLK<1> transitions, and output the latched reference clock RCLK as a first level signal FO<1>.

The second flip-flop 120 may latch the reference clock RCLK at a time that the second divided clock DCLK<2> transitions, and output the latched reference clock RCLK as a second level signal FO<2>.

The third flip-flop 130 may latch the reference clock RCLK at a time that the third divided clock DCLK<3> transitions, and output the latched reference clock RCLK as a third level signal FO<3>.

The fourth flip-flop 140 may latch the reference clock RCLK at a time that the fourth divided clock DCLK<4> transitions, and output the latched reference clock RCLK as a fourth level signal FO<4>.

The levels of the first to fourth divided clocks DCLK<1:4> through which the first to fourth flip-flops 110 to 140 latch the reference clock RCLK to generate the first to fourth level signals FO<1:4>, respectively, may be set depending on the embodiment.

That is, the frequency comparison circuit 15 may compare the phases of the first to fourth divided clocks DCLK<1:4> to the phase of the reference clock RCLK, and generate the first to fourth level signals FO<1:4> according to the comparison result. The operation of the frequency comparison circuit 15 to generate the first to fourth level signals FO<1:4> will be described in detail later with reference to the corresponding drawing.

The monitoring signal generation circuit 16 may generate the first to Nth monitoring signals MS<1:N> of which a level combination is changed according to a level combination of the first to fourth level signals FO<1:4>, in response to the enable signal EN and the locking signal LOCK.

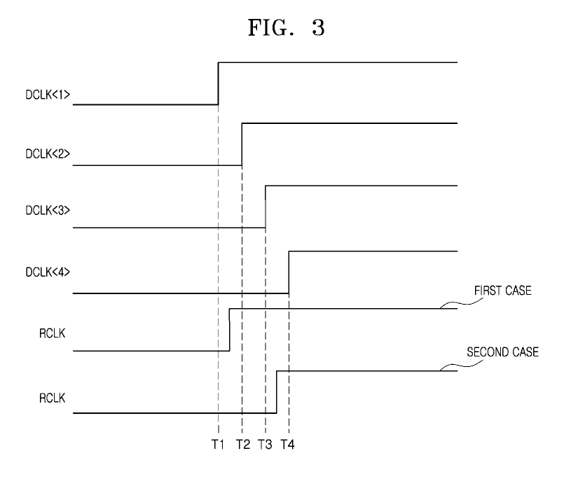

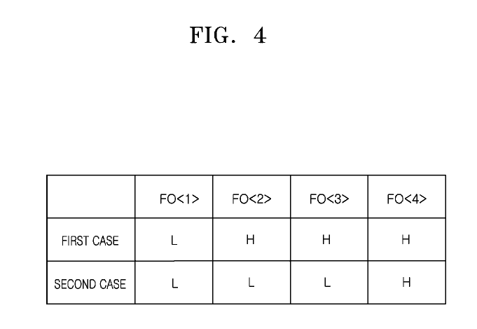

More specifically, referring to FIGS. 3 and 4, operation of the frequency comparison circuit will be described as follows.

Before operation of the frequency comparison circuit is described, the operation of generating the first to fourth divided clocks DCLK<1:K> will be described as follows.

At a time point T1, the first divided clock DCLK<1> may transition from a logic low level to a logic high level.

At a time point T2, the second divided clock DCLK<2> may transition from a logic low level to a logic high level.

At a time point T3, the third divided clock DCLK<3> may transition from a logic low level to a logic high level.

At a time point T4, the fourth divided clock DCLK<4> may transition from a logic low level to a logic high level.

At this time, a phase of the clock CLK may be divided to generate the first to fourth divided clocks DCLK<1:4> which sequentially transitions.

First, a case in which the reference clock RCLK transitions between the time points T1 and T2 (first case) will be described as follows.

At the time point T1, the first flip-flop 110 may latch the low-level reference clock RCLK according to the first divided clock DCLK<1> which transitions from a logic low level to a logic high level, and generate the first level signal FO<1> at a logic low level.

At the time point T2, the second flip-flop 120 may latch the high-level reference clock RCLK according to the second divided clock DCLK<2> which transitions from a logic low level to a logic high level, and generate the second level signal FO<2> at a logic high level.

At the time point T3, the third flip-flop 130 may latch the high-level reference clock RCLK according to the third divided clock DCLK<3> which transitions from a logic low level to a logic high level, and generate the third level signal FO<3> at a logic high level.

At the time point T4, the fourth flip-flop 140 may latch the high-level reference clock RCLK according to the fourth divided clock DCLK<4> which transitions from a logic low level to a logic high level, and generate the fourth level signal FO<4> at a logic high level.

That is, when the reference clock RCLK transitions between the time points T1 and T2 (first case), the first level signal FO<1> may be generated at a logic low level L, the second level signal FO<2> may be generated at a logic high level H, the third level signal FO<3> may be generated at a logic high level H, and the fourth level signal FO<4> may be generated at a logic high level H, as illustrated in FIG. 4.

Next, a case in which the reference clock RCLK transitions between the time points T3 and T4 (second case) will be described as follows.

At the time point T1, the first flip-flop 110 may latch the low-level reference clock RCLK according to the first divided clock DCLK<1> which transitions from a logic low level to a logic high level, and generate the first level signal FO<1> at a logic low level.

At the time point T2, the second flip-flop 120 may latch the low-level reference clock RCLK according to the second divided clock DCLK<2> which transitions from a logic low level to a logic high level, and generate the second level signal FO<2> at a logic low level.

At the time point T3, the third flip-flop 130 may latch the low-level reference clock RCLK according to the third divided clock DCLK<3> which transitions from a logic low level to a logic high level, and generate the third level signal FO<3> at a logic low level.

At the time point T4, the fourth flip-flop 140 may latch the high-level reference clock RCLK according to the fourth divided clock DCLK<4> which transitions from a logic low level to a logic high level, and generate the fourth level signal FO<4> at a logic high level.

That is, when the reference clock RCLK transitions between the time points T3 and T4 (second case), the first level signal FO<1> may be generated at a logic low level L, the second level signal FO<2> may be generated at a logic low level L, the third level signal FO<3> may be generated at a logic low level L, and the fourth level signal FO<4> may be generated at a logic high level H, as illustrated in FIG. 4.

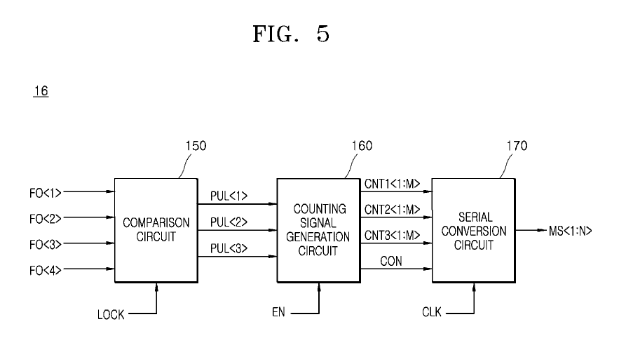

Referring to FIG. 5, the monitoring signal generation circuit 16 in accordance with the present embodiment may include a comparison circuit 150, a counting signal generation circuit 160, and a serial conversion circuit 170.

The comparison circuit 150 may generate first to third pulse signals PUL<1:3> which are reset at a time that the locking signal LOCK is enabled, and include pulses generated by comparing the levels of the first to fourth level signals FO<1:4>.

The counting signal generation circuit 160 may generate first to third counting signals CNT1<1:M>, CNT2<1:M>, and CNT3<1:M> which are reset at a time that the enable signal EN is enabled, and counted in response to pulses of the first to third pulse signals PUL<1:3>. The counting signal generation circuit 160 may generate a control signal CON which is enabled at a time that the enable signal EN is disabled.

When the control signal CON is enabled, the serial conversion circuit 170 may serialize the first to third counting signals CNT<1:M>, CNT2<1:M> and CNT3<1:M> in synchronization with the clock CLK, and output the serialized signals as the first to Nth monitoring signals MS<1:N>.

More specifically, the serial conversion circuit 170 may output the first counting signal CNT1<1:M> as the first to Mth monitoring signals MS<1:M>, output the second counting signal CNT2<1:M> as the (M+1)th to 2Mth monitoring signals MS<M+1:2M>, and output the third counting signal CNT3<1:M> as the (2M+1)th to Nth monitoring signals MS<2M+1:N>, in synchronization with the clock CLK. The bits N of the first to Nth monitoring signals MS<1:N> may be set to the sum of bits M of the first to third counting signals CNT<1:M>, CNT2<1:M> and CNT3<1:M>.

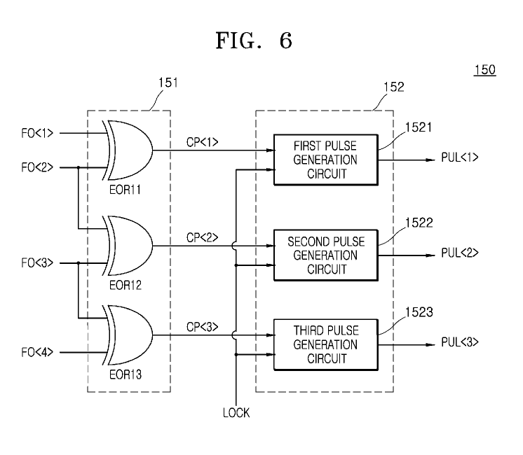

Referring to FIG. 6, the comparison circuit 150 in accordance with the present embodiment may include a comparison signal generation circuit 151 and a pulse signal generation circuit 152.

The comparison signal generation circuit 151 may include a first logic element EOR11, a second logic element EOR12, and a third logic element EOR13. In one example, each of the first logic element EOR11, the second logic element EOR12, and the third logic element EOR13 may be an XOR circuit or gate.

The first logic element EOR11 may generate a first comparison signal CP<1> by comparing logic levels of the first and second level signals FO<1:2>. When the logic level of the first level signal FO<1> is different from the logic level of the second level signal FO<2>, the first logic element EOR11 may generate the first comparison signal CP<1> at a logic high level. The first logic element EOR11 may generate the first comparison signal CP<1> by performing an XOR operation on the first and second level signals FO<1:2>.

The second logic element EOR12 may generate a second comparison signal CP<2> by comparing the logic levels of the second and third level signals FO<2:3>. When the logic level of the second level signals FO<2> is different from the logic level of the third level signal FO<3>, the second logic element EOR12 may generate the second comparison signal CP<2> at a logic high level. The second logic element EOR12 may generate the second comparison signal CP<2> by performing an XOR operation on the second and third level signals FO<2:3>.

The third logic element EOR13 may generate a third comparison signal CP<3> by comparing the logic levels of the third and fourth level signals FO<3:4>. When the logic level of the third level signal FO<3> is different from the logic level of the fourth level signal FO<4>, the third logic element EOR13 may generate the third comparison signal CP<3> at a logic high level. The third logic element EOR13 may generate the third comparison signal CP<3> by performing an XOR operation on the third and fourth level signals FO<3:4>.

That is, the comparison signal generation circuit 151 may generate the first to third comparison signals CP<1:3> by comparing the logic levels of the first to fourth level signals FO<1:4>.

The pulse signal generation circuit 152 may include a first pulse generation circuit 1521, a second pulse generation circuit 1522, and a third pulse generation circuit 1523.

The first pulse generation circuit 1521 may generate the first pulse signal PUL<1> which is reset in response to the locking signal LOCK, and includes a pulse generated when the first comparison signal CP<1> is inputted at a logic high level.

The second pulse generation circuit 1522 may generate the second pulse signal PUL<2> which is reset in response to the locking signal LOCK, and includes a pulse generated when the second comparison signal CP<2> is inputted at a logic high level.

The third pulse generation circuit 1523 may generate the third pulse signal PUL<3> which is reset in response to the locking signal LOCK, and includes a pulse generated when the third comparison signal CP<3> is inputted at a logic high level.

That is, the pulse signal generation circuit 152 may generate the first to third pulse signals PUL<1:3> which are reset in response to the locking signal LOCK, and include pulses generated in response to the first to third comparison signals CP<1:3>. The logic levels of the first to third pulse signals PUL<1:3> which are reset may be set in various manners depending on embodiments. The logic levels of the pulses included in the first to third pulse signals PUL<1:3> may be set in various manners depending on embodiments.

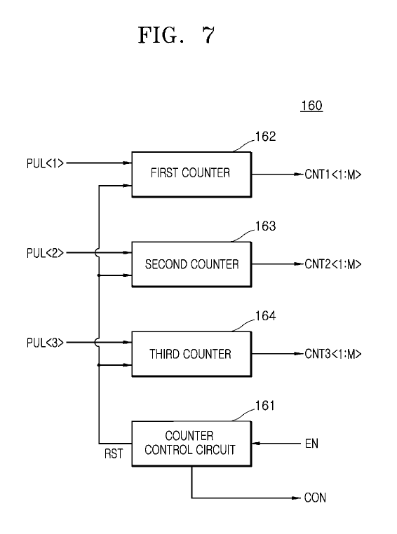

Referring to FIG. 7, the counting signal generation circuit 160 in accordance with the present embodiment may include a counter control circuit 161, a first counter 162, a second counter 163, and a third counter 164.

The counter control circuit 161 may generate a reset signal RST including a pulse which is generated when the enable signal EN is enabled, and generate the control signal CON which is enabled when the enable signal EN is disabled.

The first counter 162 may generate the first counting signal CNT1<1:M> which is reset in response to a pulse of the reset signal RST, and counted in response to the first pulse signal PUL<1>. The first counter 162 may generate the first counting signal CNT1<1:M> which is counted in response to a number of pulses included in the first pulse signal PUL<1>.

The second counter 163 may generate the second counting signal CNT2<1:M> which is reset in response to a pulse of the reset signal RST, and counted in response to the second pulse signal PUL<2>. The second counter 163 may generate the second counting signal CNT2<1:M> which is counted in response to a number of pulses included in the second pulse signal PUL<2>.

The third counter 164 may generate the third counting signal CNT3<1:M> which is reset in response to a pulse of the reset signal RST, and counted in response to the third pulse signal PUL<3>. The third counter 164 may generate the third counting signal CNT3<1:M> which is counted in response to a number of pulses included in the third pulse signal PUL<3>.

That is, the counting signal generation circuit 160 may generate first to third counting signals CNT1<1:M>, CNT2<1:M> and CNT3<1:M> which are reset at a time that the enable signal EN is enabled, and counted in response to the pulses of the first to third pulse signals PUL<1:3>. The counting signal generation circuit 160 may generate a control signal CON which is enabled at a time that the enable signal EN is disabled.

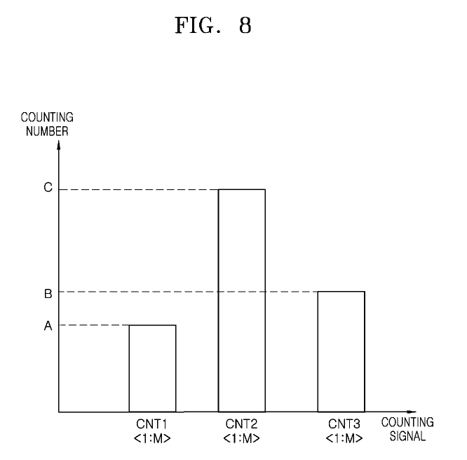

More specifically, referring to FIG. 8, operation of the counting signal generation circuit 160 will be described as follows.

When a pulse of the first pulse signal PUL<1> is inputted A times, the first counter 162 may generate the first counting signal CNT1<1:M> which is counted A times.

When a pulse of the second pulse signal PUL<2> is inputted B times, the second counter 163 may generate the second counting signal CNT2<1:M> which is counted B times.

When a pulse of the third pulse signal PUL<3> is inputted C times, the third counter 164 may generate the third counting signal CNT3<1:M> which is counted C times.

The operation of the semiconductor system in accordance with the present embodiment will be described as follows. In the following descriptions, the case in which the first to third counting signals are counted as illustrated in FIG. 8 will be taken as an example.

The first semiconductor device 1 may output the clock CLK, and receive/output the first to Kth data DQ<1:K>.

The multi-phase clock generation circuit 11 may generate the first to fourth divided clocks DCLK<1:4> by dividing the frequency of the clock CLK inputted from outside the multi-phase clock generation circuit 11, controlling the phases of the first to fourth divided clocks DCLK<1:4>, and generating the locking signal LOCK which is enabled at a time that the phase control operation is completed.

The transmission path 12 may transmit the clock CLK as the internal clock ICLK. At this time, while the transmission path 12 transmits the clock CLK as the internal clock ICLK, a jitter may irregularly occur according to PVT variations.

The logic circuit 14 may generate the reference clock RCLK by buffering the internal clock ICLK in response to the enable signal EN.

The frequency comparison circuit 15 may compare the phases of the first to fourth divided clocks DCLK<1:4> to the phase of the reference clock RCLK, and generate the first to fourth level signals FO<1:4> according to the comparison result.

The comparison circuit 150 of the monitoring signal generation circuit 16 may compare the levels of the first to fourth level signals FO<1:4>, generate pulses of the first pulse signal PUL<1> A times, generate pulses of the second pulse signal PUL<2> B times, and generate pulses of the third pulse signal PUL<3> C times.

The counting signal generation circuit 160 may count the first to third counting signals CNT1<1:M>, CNT2<1:M> and CNT3<1:M> in response to the pulses of the first to third pulse signals PUL<1:3>. The counting signal generation circuit 160 may generate the control signal CON which is enabled at a time that the enable signal EN is disabled, after the counting operation for the first to third counting signals CNT1<1:M>, CNT2<1:M> and CNT3<1:M> is completed. At this time, the first counting signal CNT1<1:M> may be counted A times, the second counting signal CNT2<1:M> may be counted B times, and the third counting signal CNT3<1:M> may be counted C times.

Since the control signal CON is enabled, the serial conversion circuit 170 may output the first counting signal CNT1<1:M> as the first to Mth monitoring signals MS<1:M>, output the second counting signal CNT2<1:M> as the (M+1)th to 2Mth monitoring signals MS<M+1:2M>, and output the third counting signal CNT3<1:M> as the (2M+1)th to Nth monitoring signals MS<2M+1:N>, in synchronization with the clock CLK.

The first semiconductor device 1 may receive the first to Nth monitoring signals MS<1:N>, and detect a jitter of the transmission path 12 installed in the second semiconductor device 2, where the jitter may occur according to a level combination of the plurality of monitoring signals MS<1:N>.

More specifically, the first semiconductor device 1 may detect the logic levels of the bits included in the first to Nth monitoring signals MS<1:N>, and confirm that the first counting signal CNT1<1:M> is counted A times, the second counting signal CNT2<1:M> is counted B times, and the third counting signal CNT3<1:M> is counted C times. That is, the first semiconductor device 1 may detect the counting numbers of the first to third counting signals CNT<1:M>, CNT2<1:M> and CNT3<1:M> which are counted according to the phase differences between the internal clock ICLK and the first to fourth divided clocks DCLK<1:4>, and detect a jitter of the transmission path 12 installed in the second semiconductor device 2.

The semiconductor system in accordance with the present embodiment may detect a jitter which occurs in the transmission path through which the clock is transmitted. Furthermore, the semiconductor system may output the monitoring signal. The monitoring signal may include the jitter information which occurs in the internal transmission path through which the clock is transmitted, and the semiconductor system may detect the jitter of the internal transmission path.

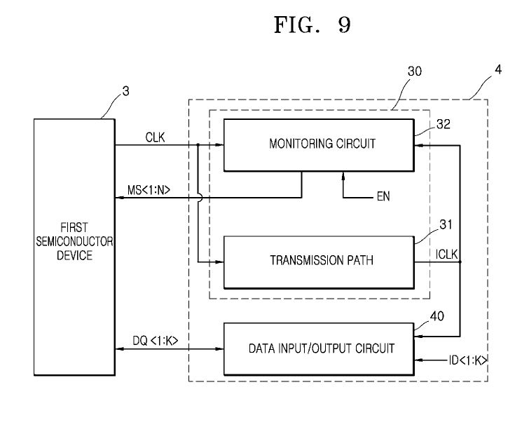

FIG. 9 is a block diagram illustrating a configuration of a semiconductor system in accordance with another embodiment of the present disclosure.

As illustrated in FIG. 9, the semiconductor system in accordance with the present embodiment may include first and second semiconductor devices 3 and 4. The second semiconductor device 4 may include a jitter detection circuit 30 and a data input/output circuit 40.

The first semiconductor device 1 may output a clock CLK, receive and output first to Kth data DQ<1:K>, and receive first to Nth monitoring signals MS<1:N>. The clock CLK may be set to a signal which periodically toggles. The first to Kth data DQ<1:K> and the first to Nth monitoring signals MS<1:N> may be transmitted through lines for transmitting one or more of an address, a command, and data. The first to Kth data DQ<1:K> and the first to Nth monitoring signals MS<1:N> may be sequentially transmitted through one line or transmitted through separate lines. The first to Nth monitoring signals MS<1:N> may include jitter information of a transmission path 31 installed in the second semiconductor device 4 which will be described below. That is, the first semiconductor device 3 may detect a jitter of a transmission path 31 installed in the second semiconductor device 4.

The jitter detection circuit 30 may include the transmission path 31 and a monitoring circuit 32.

The transmission path 31 may transmit the clock CLK as an internal clock ICLK. The transmission path 31 may be set to a path for transmitting a signal in a general semiconductor device. While the transmission path 31 transmits a signal, a jitter may irregularly occur according to PVT variations.

The monitoring circuit 32 may generate the first to Nth monitoring signals MS<1:N> of which the level combination is changed according to phase differences between the internal clock ICLK and first to fourth divided clocks DCLK<1:4> generated by dividing a frequency of the clock CLK.

That is, the jitter detection circuit 30 may generate the first to Nth monitoring signals MS<1:N> based on the phase differences between the first to fourth divided clocks DCLK<1:4> and the internal clock ICLK inputted through the transmission path 31.

The data input/output circuit 40 may transmit the first to Kth data DQ<1:K> inputted from outside the data input/output circuit 40 as first to Kth internal data ID<1:K> in synchronization with the internal clock ICLK during a write operation. The data input/output circuit 40 may transmit the first to Kth internal data ID<1:K> as the first to Kth data DQ<1:K> in synchronization with the internal clock ICLK during a read operation. The first to Kth internal data ID<1:K> may indicate data stored in memory cells (not illustrated) included in the second semiconductor device 4.

That is, the second semiconductor device 4 may generate the first to Nth monitoring signals MS<1:N> of which a level combination is changed according to the phase differences between the internal clock ICLK generated through the transmission path 31 for transmitting the clock CLK and the first to fourth divided clocks DCLK<1:4> obtained by dividing the frequency of the clock CLK. The second semiconductor device 4 may receive/output the first to Kth data DQ<1:K> in synchronization with the internal clock ICLK.

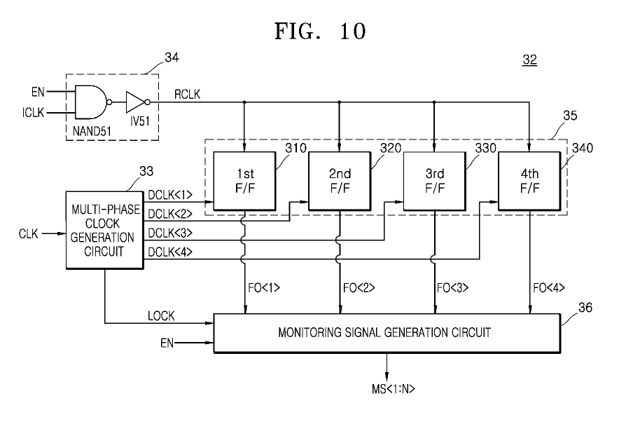

Referring to FIG. 10, the monitoring circuit 32 in accordance with the present embodiment may include a multi-phase clock generation circuit 33, a logic circuit 34, a frequency comparison circuit 35, and a monitoring signal generation circuit 36.

The multi-phase clock generation circuit 33 may generate the first to fourth divided clocks DCLK<1:4> by dividing the frequency of the clock CLK, and controlling phases of the first to fourth divided clocks DCLK<1:4>. The multi-phase clock generation circuit 33 may generate a locking signal LOCK which is enabled when a phase control operation for the first to fourth divided clocks DCLK<1:4> is completed. The multi-phase clock generation circuit 33 may be implemented with a general PLL circuit or DLL circuit which controls a phase of the clock CLK.

The logic circuit 34 may include a NAND gate NADN51 and an inverter IV51, and generate a reference clock RCLK by buffering the internal clock ICLK in response to an enable signal EN. When the enable signal EN is enabled to a logic high level, the logic circuit 34 may generate the reference clock RCLK by buffering the internal clock ICLK. The enable signal EN may be enabled to detect a jitter of the transmission path 31.

The frequency comparison circuit 35 may include a first flip-flop 310, a second flip-flop 320, a third flip-flop 330, and a fourth flip-flop 340.

The first flip-flop 310 may latch the reference clock RCLK at a time that the first divided clock DCLK<1> transitions, and output the latched reference clock RCLK as a first level signal FO<1>.

The second flip-flop 320 may latch the reference clock RCLK at a time that the second divided clock DCLK<2> transitions, and output the latched reference clock RCLK as a second level signal FO<2>.

The third flip-flop 330 may latch the reference clock RCLK at a time that the third divided clock DCLK<3> transitions, and output the latched reference clock RCLK as a third level signal FO<3>.

The fourth flip-flop 340 may latch the reference clock RCLK at a time that the fourth divided clock DCLK<4> transitions, and output the latched reference clock RCLK as a fourth level signal FO<4>.

The levels of the first to fourth divided clocks DCLK<1:4> through which the first to fourth flip-flops 310 to 340 latch the reference clock RCLK to generate the first to fourth level signals FO<1:4>, respectively, may be set in various manners depending on embodiments.

That is, the frequency comparison circuit 35 may compare the phases of the first to fourth divided clocks DCLK<1:4> to the phase of the reference clock RCLK, and generate the first to fourth level signals FO<1:4> according to the comparison result. Since the frequency comparison circuit 35 is configured and operates in a substantially similar manner as the frequency comparison circuit 15 of FIG. 2, detailed descriptions thereof are omitted.

The monitoring signal generation circuit 36 may generate the first to Nth monitoring signals MS<1:N> according to a level combination of the first to fourth level signals FO<1:4>, in response to the enable signal EN and the locking signal LOCK. Since the monitoring signal generation circuit 36 is configured and operates in a substantially similar manner as the monitoring signal generation circuit 16 of FIG. 5, detailed descriptions thereof are omitted.

The semiconductor system in accordance with the present embodiment may detect a jitter which occurred in the transmission path through which a clock is transmitted. Furthermore, the semiconductor system in accordance with the present embodiment may output the monitoring signal. The monitoring signal may include the jitter information which occurred in the internal transmission path through which the clock is transmitted, and the semiconductor system may detect the jitter of the internal transmission path.

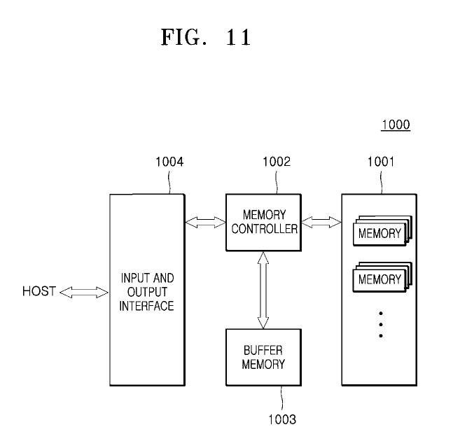

The semiconductor device and the semiconductor system which have been described with reference to FIGS. 1 to 10 may be applied to electronic systems including a memory system, a graphic system, a computing system, and a mobile system. For example, referring to FIG. 11, an electronic system 1000 in accordance with an embodiment may include a data storage 1001, a memory controller 1002, a buffer memory 1003, and an input/output interface 1004.

The data storage 1001 may store data applied from the memory controller 1002, read the stored data, and output the read data to the memory controller 1002, according to a control signal from the memory controller 1002. The data storage 1001 may include the second semiconductor device 2 illustrated in FIG. 1 and the second semiconductor device 4 illustrated in FIG. 9. The data storage 1001 may include a nonvolatile memory which can continuously store data stored therein even though power supply is cut off. The nonvolatile memory may include a flash memory (NOR Flash Memory, NAND Flash Memory), PRAM (Phase Change Random Access Memory), RRAM (Resistive Random Access Memory), STTRAM (Spin Transfer Torque Random Access Memory), and MRAM (Magnetic Random Access Memory).

The memory controller 1002 may decode a command applied from an external device (host device) through the input/output interface 1004, and control the data input/output for the data storage 1001 and the buffer memory 1003 according to the decoding result. The memory controller 1002 may include the first semiconductor device 1 illustrated in FIG. 1 and the first semiconductor device 3 illustrated in FIG. 9. In FIG. 11, the memory controller 1002 is represented by one block. However, the memory controller 1002 may include a controller for controlling a nonvolatile memory and a controller for controlling the buffer memory 1003 which is a volatile memory.

The buffer memory 1003 may temporarily store data which is to be processed by the memory controller 1002, that is, data which is to be inputted to or outputted from the data storage 1001. The buffer memory 1003 may store the data applied from the memory controller 1002 according to the control signal. The buffer memory 1003 may read the stored data and output the read data to the memory controller 1002. The buffer memory 1003 may include a volatile memory such as DRAM (Dynamic Random Access Memory), mobile DRAM or SRAM (Static Random Access Memory).

The input/output interface 1004 may provide a physical connection between the memory controller 1002 and an external device (host), receive a control signal for controlling the memory controller 1002 to input or output data to or from the external device, and exchange data with the external device. The input/output interface 1004 may include one of various interface protocols such as USB (Universal Serial Bus), MMC (Multi Media Card), PCI-E (Peripheral Component Interconnect Express), SCSI (Small Computer System Interface), SAS (Serial Attached SCSI), SATA (Serial Advanced Technology Attachment), PATA (Parallel Advanced Technology Attachment), ESDI (Enhanced Small Device Interface), and IDE (Integrated Drive Electronics).

The electronic system 1000 may be used as a secondary memory device or external storage device of the host device. The electronic system 1000 may include an SSD (Solid State Disk), a USB memory, an SD (Secure Digital) card, an mSD (mini Secure Digital) card, a micro SD card, an SDHC (Secure Digital High Capacity) card, a memory stick card, an SM (Smart Media) card, an MMC, an eMMC (Embedded MMC), a CF (Compact Flash) card and the like.

In accordance with the embodiments of the present disclosure, the jitter detection circuit and the semiconductor system can detect a jitter which occurred in the transmission path through which the clock is transmitted.

Furthermore, the jitter detection circuit and the semiconductor system can output a monitoring signal, the monitoring signal including jitter information which occurred in the internal transmission path through which the clock is transmitted, and thus detect the jitter of the internal transmission path outside.

Although preferred embodiments of the disclosure have been disclosed for illustrative purposes, those skilled in the art will appreciate that various modifications, additions and substitutions are possible, without departing from the scope and spirit of the disclosure as defined in the accompanying claims.

What is claimed is:

1. A jitter detection circuit comprising:
a multi-phase clock generation circuit configured to generate a plurality of divided clocks by dividing a frequency of a clock inputted from outside the multi-phase clock generation circuit and controlling a phase of the clock, and generate a locking signal which is enabled when a phase control operation for the plurality of divided clocks is completed;
a transmission path configured to transmit the clock as an internal clock; and
a monitoring circuit configured to generate a plurality of monitoring signals of which a level combination is changed according to phase differences between the internal clock and the plurality of divided clocks.

2. The jitter detection circuit of claim 1, wherein the plurality of monitoring signals are generated by comparing the phase of the internal clock to the phases of the plurality of divided clocks.

3. The jitter detection circuit of claim 1, wherein the plurality of monitoring signals comprise jitter information of the transmission path.

4. The jitter detection circuit of claim 1, wherein the monitoring circuit comprises:
a logic circuit configured to generate a reference clock by buffering the internal clock in response to an enable signal;
a frequency comparison circuit configured to compare the phases of the plurality of divided clocks to the phase of the reference clock, and generate a plurality of level signals according to the comparison result; and
a monitoring signal generation circuit configured to generate the plurality of monitoring signals according to a level combination of the plurality of level signals in response to the enable signal and the locking signal.

5. The jitter detection circuit of claim 4, wherein the enable signal is enabled to detect a jitter of the transmission path.

6. The jitter detection circuit of claim 4, wherein the frequency comparison circuit comprises:
a first flip-flop configured to latch the reference clock at a time that the first divided clock transitions, and output the latched reference clock as a first level signal;
a second flip-flop configured to latch the reference clock at a time that the second divided clock transitions, and output the latched reference clock as a second level signal;
a third flip-flop configured to latch the reference clock at a time that the third divided clock transitions, and output the latched reference clock as a third level signal; and
a fourth flip-flop configured to latch the reference clock at a time that the fourth divided clock transitions, and output the latched reference clock as a fourth level signal.

7. The jitter detection circuit of claim 4, wherein the monitoring signal generation circuit comprises:
a comparison circuit configured to generate first to third pulse signals which are reset at a time that the locking signal is enabled, and include pulses generated by comparing levels of the first to fourth level signals;
a counting signal generation circuit configured to generate first to third counting signals which are reset at a time that the enable signal is enabled, and counted in response to pulses of the first to third pulse signals, and generate a control signal which is enabled at a time that the enable signal is disabled; and
a serial conversion circuit configured to serialize the first to third counting signals in synchronization with the clock in response to the control signal, and output the serialized signals as the plurality of monitoring signals.

8. The jitter detection circuit of claim 7, wherein the comparison circuit comprises:
a comparison signal generation circuit configured to generate first to third comparison signals by comparing the levels of the first to fourth level signals; and
a pulse signal generation circuit configured to generate the first to third pulse signals which are reset in response to the locking signal, and include pulses generated in response to the first to third comparison signals.

9. The jitter detection circuit of claim 8, wherein the comparison signal generation circuit comprises:
a first logic element configured to generate the first comparison signal by comparing logic levels of the first and second level signals;
a second logic element configured to generate the second comparison signal by comparing logic levels of the second and third level signals; and
a third logic element configured to generate the third comparison signal by comparing logic levels of the third and fourth level signals.

10. The jitter detection circuit of claim 8, wherein the pulse signal generation circuit comprises:
a first pulse generation circuit configured to generate the first pulse signal which is reset in response to the locking signal, and includes a pulse generated in response to the first comparison signal;
a second pulse generation circuit configured to generate the second pulse signal which is reset in response to the locking signal, and includes a pulse generated in response to the second comparison signal; and
a third pulse generation circuit configured to generate the third pulse signal which is reset in response to the locking signal, and includes a pulse generated in response to the third comparison signal.

11. The jitter detection circuit of claim 7, wherein the counting signal generation circuit comprises:
a counter control circuit configured to generate a reset signal including a pulse which is generated when the enable signal is enabled, and generate the control signal which is enabled when the enable signal is disabled;
a first counter configured to generate the first counting signal which is reset in response to a pulse of the reset signal, and counted in response to the first pulse signal;
a second counter configured to generate the second counting signal which is reset in response to a pulse of the reset signal, and counted in response to the second pulse signal; and
a third counter configured to generate the third counting signal which is reset in response to a pulse of the reset signal, and counted in response to the third pulse signal.

12. A semiconductor system comprising:
a first semiconductor device configured to output a clock, receive and output data, and detect a jitter of a transmission path according to a level combination of a plurality of monitoring signals; and
a second semiconductor device configured to generate the plurality of monitoring signals of which the level combination is changed according to phase differences between an internal clock generated through the transmission path for transmitting the clock and a plurality of divided clocks obtained by dividing the frequency of the clock.

13. The semiconductor system of claim 12, wherein the plurality of monitoring signals are generated by comparing the phase of the internal clock to the phases of the plurality of divided clocks.

14. The semiconductor system of claim 12, wherein the plurality of monitoring signals comprise jitter information of the transmission path.

15. The semiconductor system of claim 12, wherein the second semiconductor device comprises:
a jitter detection circuit configured to generate the plurality of monitoring signals by comparing the phase of the internal clock to the phases of the plurality of divided clocks; and
a data input/output circuit configured to output internal data as the data or output the data as the internal data in synchronization with the internal clock.

16. The semiconductor system of claim 15, wherein the jitter detection circuit comprises:
a multi-phase clock generation circuit configured to generate the plurality of divided clocks by dividing the frequency of the clock and controlling the phase of the divided clock, and generate a locking signal which is enabled when the phase control operation for the plurality of divided clocks is completed;
the transmission path configured to transmit the clock as the internal clock; and
a monitoring circuit configured to generate a plurality of monitoring signals of which the level combination is changed according to the phase differences between the internal clock and the plurality of divided clocks.

17. The semiconductor system of claim 16, wherein the monitoring circuit comprises:
a logic circuit configured to generate a reference clock by buffering the internal clock in response to an enable signal;
a frequency comparison circuit configured to compare the phases of the plurality of divided clocks to the phase of the reference clock, and generate a plurality of level signals according to the comparison result; and
a monitoring signal generation circuit configured to generate the plurality of monitoring signals according to a level combination of the plurality of level signals in response to the enable signal and the locking signal.

18. The semiconductor system of claim 17, wherein the enable signal is enabled to detect a jitter of the transmission path.

19. The semiconductor system of claim 15, wherein the jitter detection circuit comprises:
the transmission path configured to transmit the clock as the internal clock; and
a monitoring circuit configured to generate the plurality of monitoring signals of which the level combination is changed according to the phase differences between the internal clock and the plurality of divided clocks which are generated by dividing the frequency of the clock and controlling the phase of the clock.

20. The semiconductor system of claim 19, wherein the monitoring circuit comprises:
a multi-phase clock generation circuit configured to generate the plurality of divided clocks by dividing the frequency of the clock and controlling the phase of the clock, and generate a locking signal which is enabled when the phase control operation for the plurality of divided clocks is completed;
a logic element configured to generate a reference clock by buffering the internal clock in response to an enable signal;
a frequency comparison circuit configured to compare the phases of the plurality of divided clocks to the phase of the reference clock, and generate a plurality of level signals according to the comparison result; and
a monitoring signal generation circuit configured to generate the plurality of monitoring signals according to a level combination of the plurality of level signals, in response to the enable signal and the locking signal.
